(19) United States
(12) Patent Application Publication
(10) Pub. No.: US 2026/0277417 A1
(43) Pub. Date: Sep. 17, 2026

(54) AUTOMATIC DISTANCE DISPLAY

(71) Applicant: thinAir Technologies, Inc., Covington, LA (US)

(72) Inventor: Jeremey Charbonnet, Covington, LA (US)

(21) Appl. No.: 19/555,324

(22) Filed: Mar. 3, 2026

Related U.S. Application Data
(60) Provisional application No. 63/769,931, filed on Mar. 11, 2025.

(51) Int. Cl. G06F 3/04845

(52) U.S. Cl. CPC G06F 3/04845

(57) ABSTRACT

In one implementation, a method of displaying distances between objects is performed by a device including one or more processors and non-transitory memory. The method includes displaying a plurality of objects. The method includes receiving an input to display a plurality of indications of distances between the plurality of objects. The method includes, in response to receiving the input, displaying an indication of a first distance between a first set of two of the plurality of objects at a location between the first set of the two of the plurality of objects and displaying an indication of a second distance between a second set of two of the plurality of objects at a location between the second set of the two of the plurality of objects.

### CROSS-REFERENCE TO RELATED APPLICATIONS

This application claims priority to U.S. Provisional Patent App. No. 63/769,931, filed on Mar. 11, 2025, which is hereby incorporated by reference in its entirety.

### TECHNICAL FIELD

The present disclosure generally relates to systems, methods, and devices of automatically displaying distances in a scene composing user interface.

### BACKGROUND

In various implementations, a scene composing user interface facilitates composition of a scene including one or more objects. The scene composing user interface also facilitates changing a location, rotation, and/or size of the objects of the scene. In various implementations, the scene composing user interface displays distances between objects.

### BRIEF DESCRIPTION OF THE DRAWINGS

So that the present disclosure can be understood by those of ordinary skill in the art, a more detailed description may be had by reference to aspects of some illustrative implementations, some of which are shown in the accompanying drawings.

FIGS. 1A–1N illustrate an electronic device displaying a scene composing user interface with a first scene opened during a plurality of time periods.

FIG. 2 is a flowchart representation of a method of displaying distances between objects in accordance with some implementations.

FIG. 3 is a block diagram of an example electronic device in accordance with some implementations.

In accordance with common practice the various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### SUMMARY

Various implementations disclosed herein include devices, systems, and methods for displaying distances between objects. In various implementations, the method is performed by a device having one or more processors and non-transitory memory. The method includes displaying a plurality of objects. The method includes receiving an input to display a plurality of indications of distances between the plurality of objects. The method includes, in response to receiving the input, displaying an indication of a first distance between a first set of two of the plurality of objects at a location between the first set of the two of the plurality of objects and displaying an indication of a second distance between a second set of two of the plurality of objects at a location between the second set of the two of the plurality of objects.

In accordance with some implementations, a device includes one or more processors, a non-transitory memory, and one or more programs; the one or more programs are stored in the non-transitory memory and configured to be executed by the one or more processors and the one or more programs include instructions for performing or causing performance of any of the methods described herein. In accordance with some implementations, a non-transitory computer readable storage medium has stored therein instructions, which, when executed by one or more processors of a device, cause the device to perform or cause performance of any of the methods described herein. In accordance with some implementations, a device includes: one or more processors, a non-transitory memory, and means for performing or causing performance of any of the methods described herein.

### DESCRIPTION

Numerous details are described in order to provide a thorough understanding of the example implementations shown in the drawings. However, the drawings merely show some example aspects of the present disclosure and are therefore not to be considered limiting. Those of ordinary skill in the art will appreciate that other effective aspects and/or variants do not include all of the specific details described herein. Moreover, well-known systems, methods, components, devices and circuits have not been described in exhaustive detail so as not to obscure more pertinent aspects of the example implementations described herein.

In various scene composing applications, the distance between two objects can be determined and displayed. However, populating the scene with multiple distances between different pairs of objects may be a time-consuming process. Accordingly, in various implementations, a blueprint feature is provided in which, in response to a single input, multiple distances between different pairs of objects are determined and displayed.

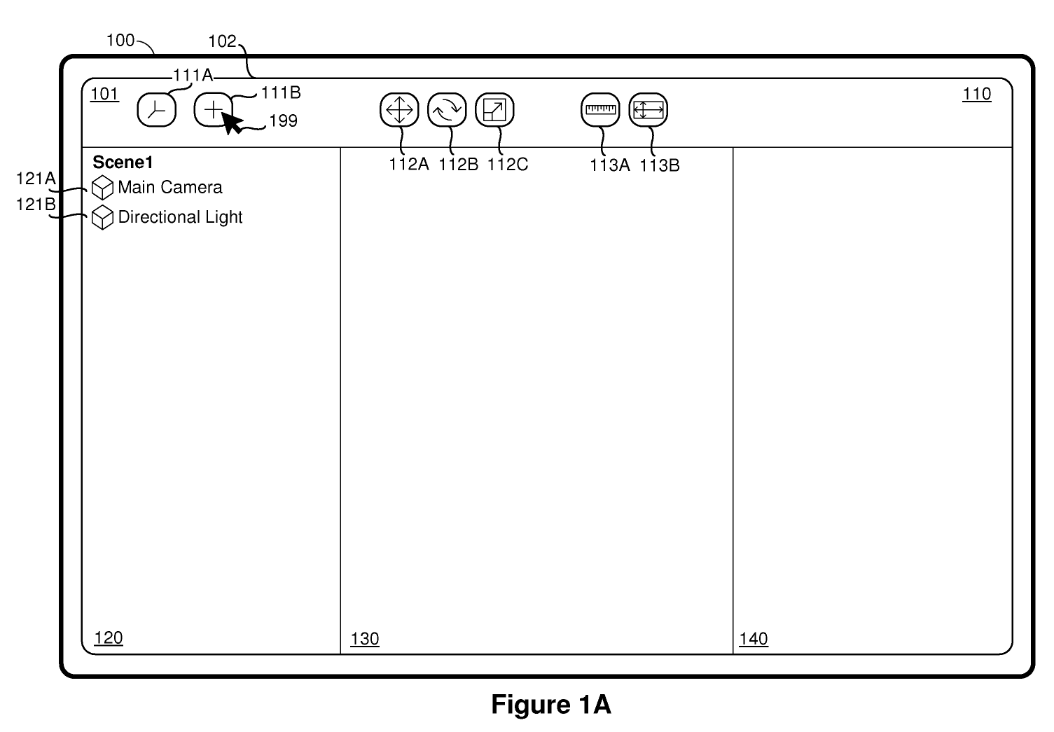

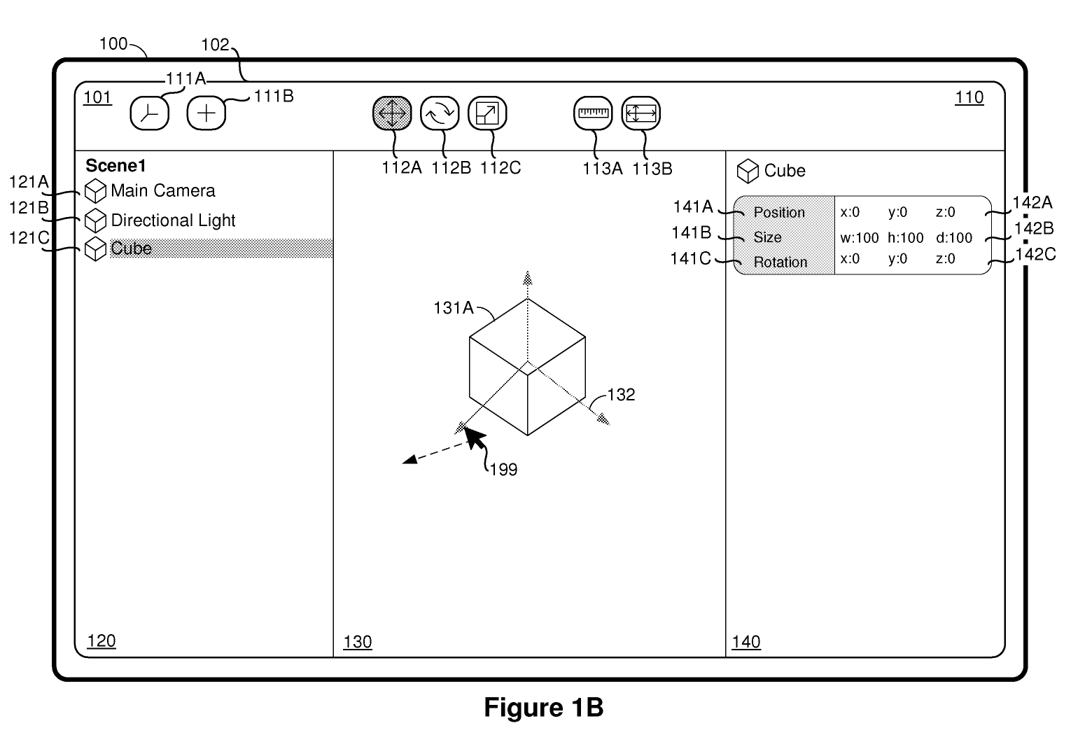

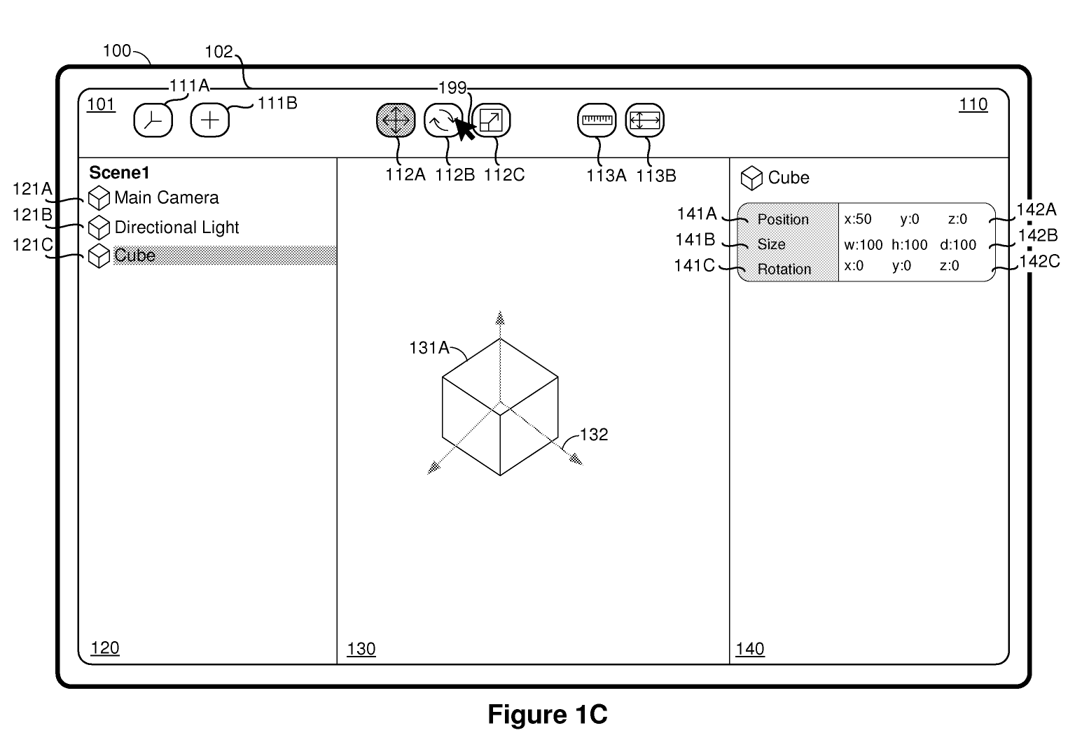

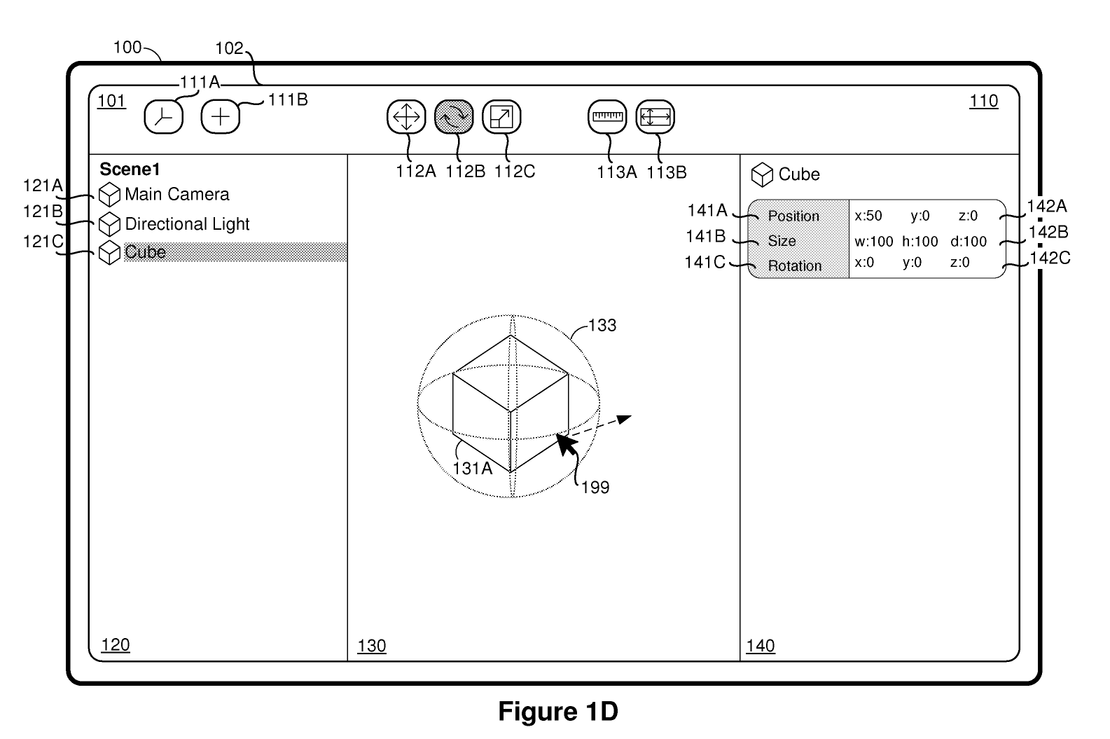

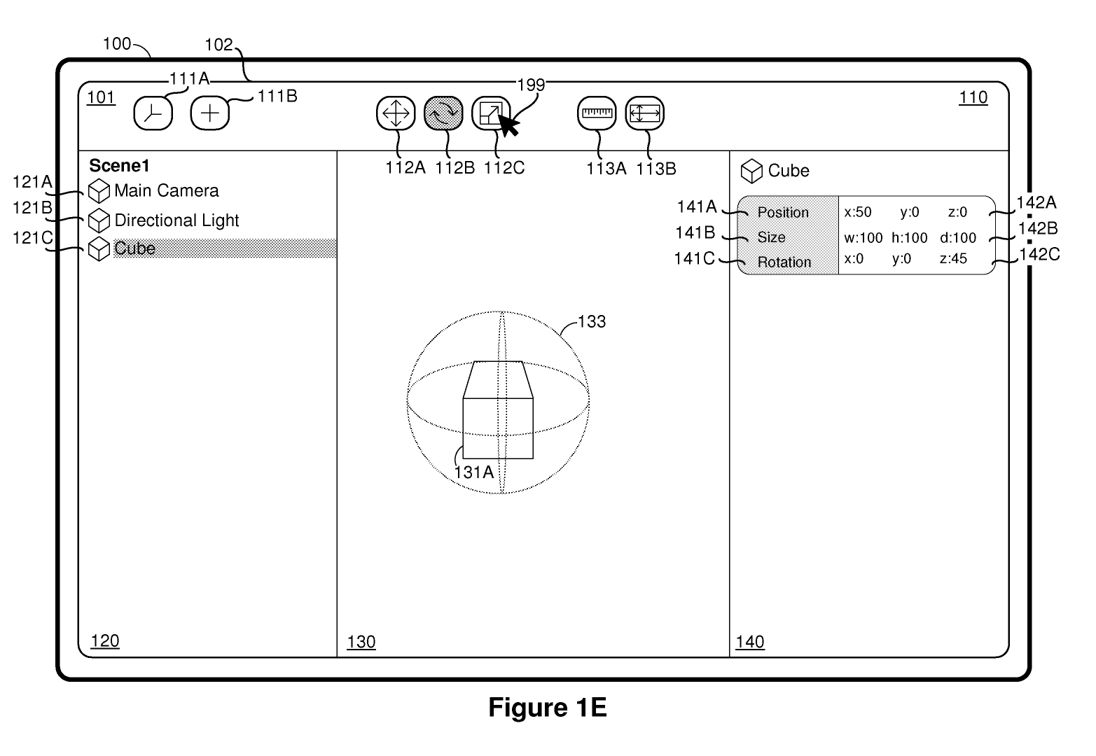

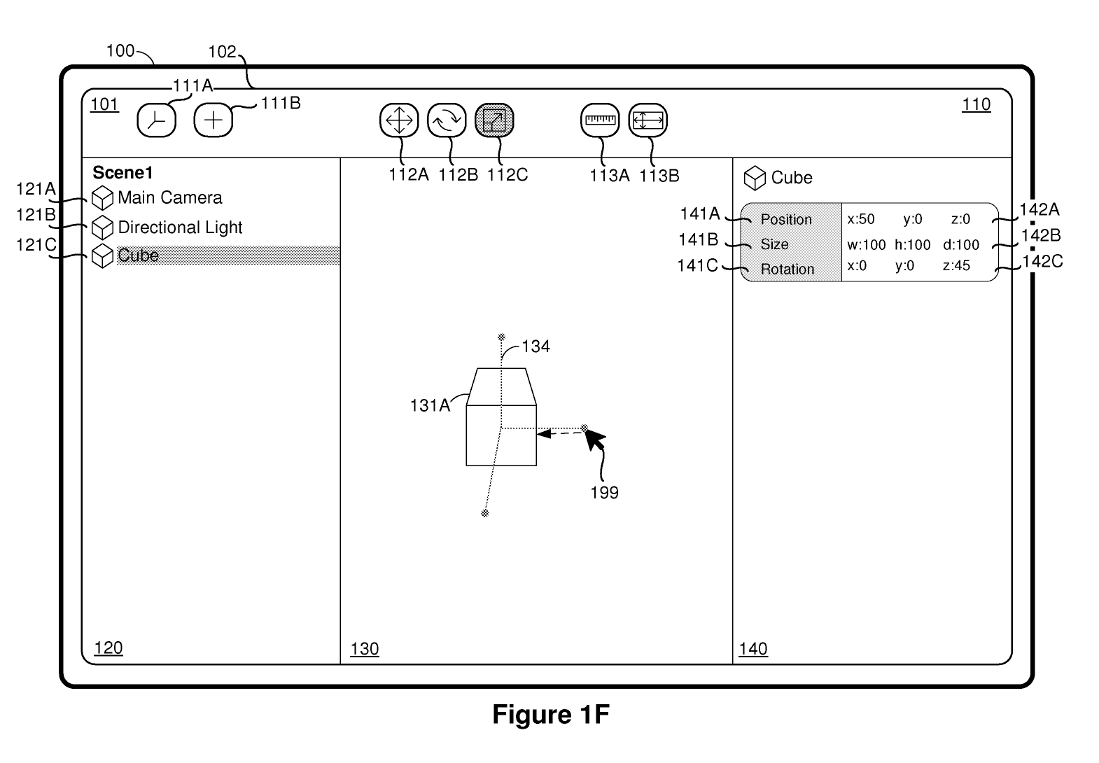

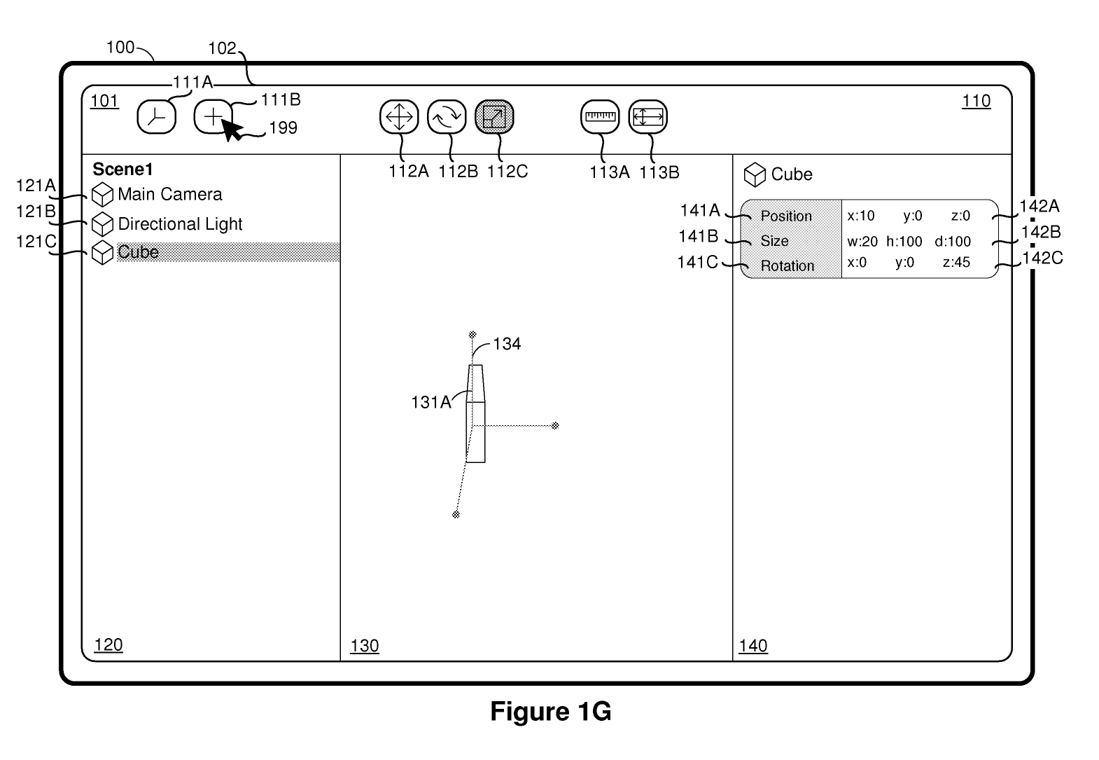

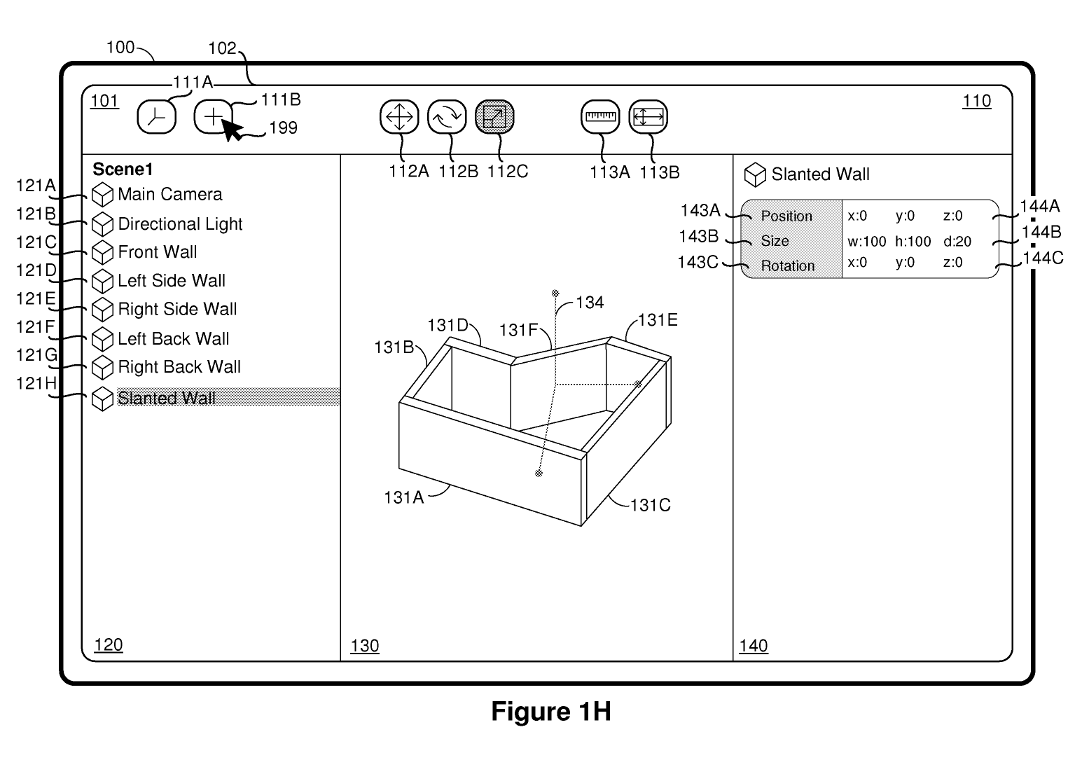

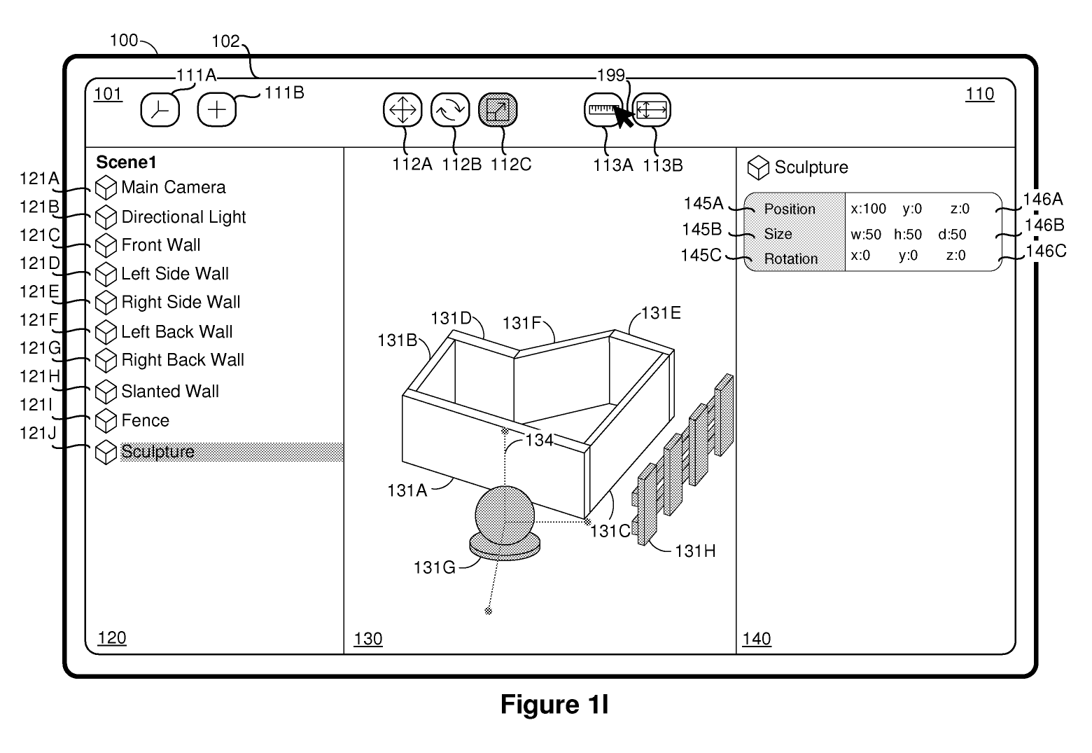

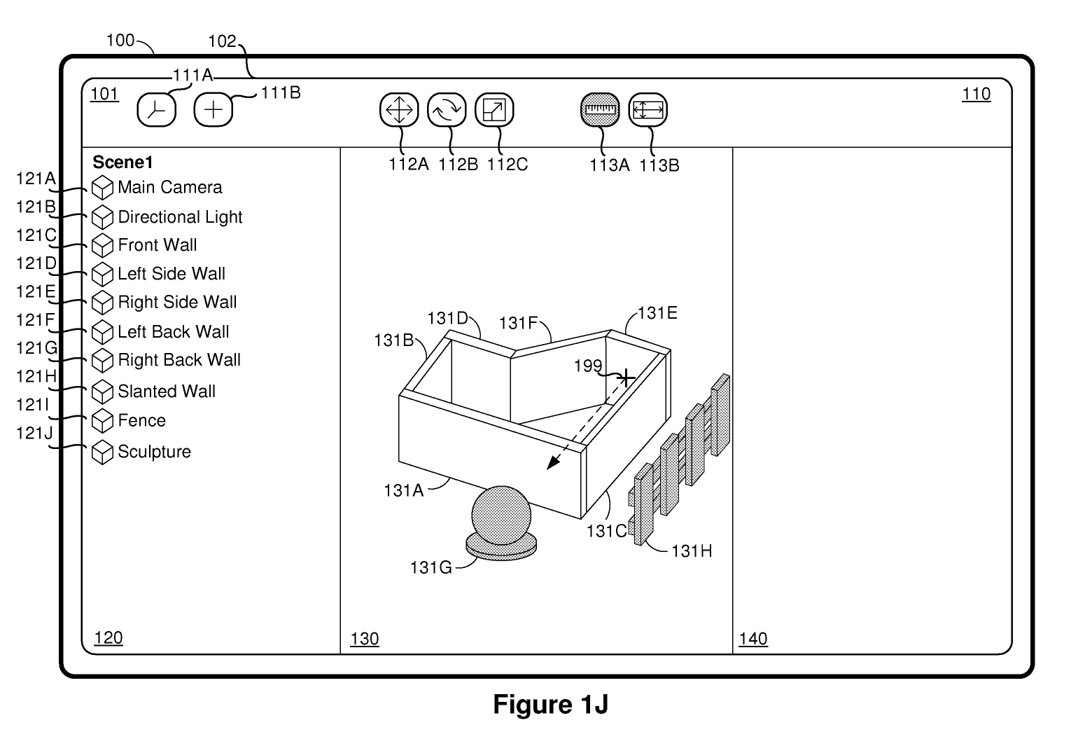

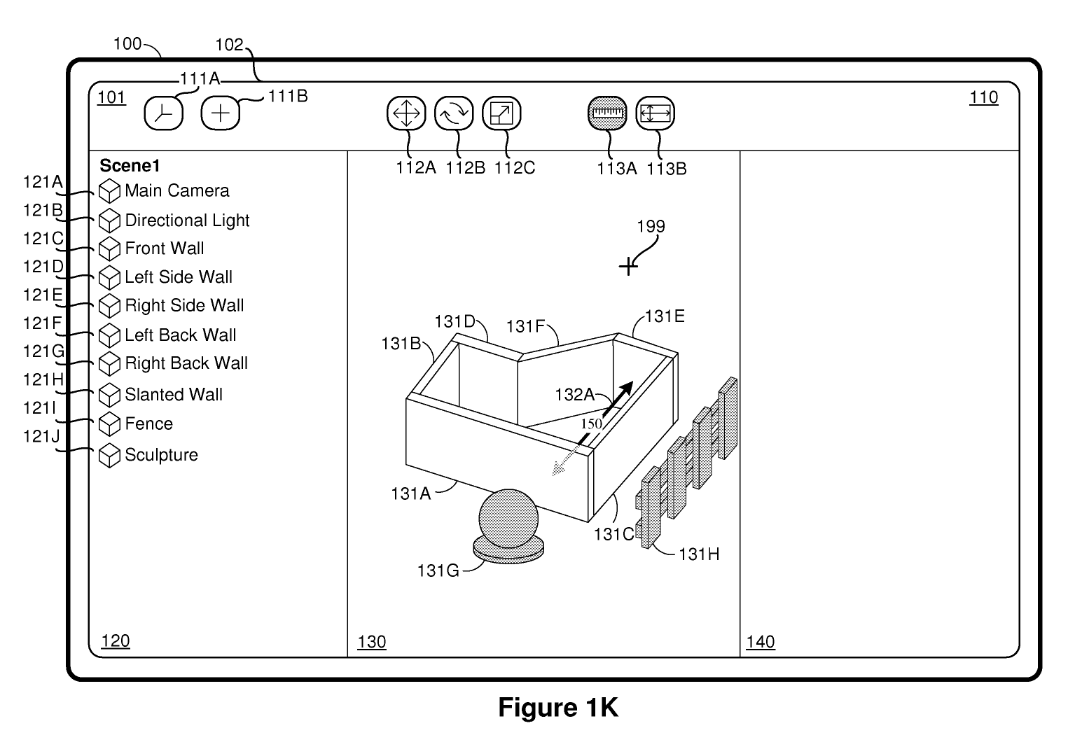

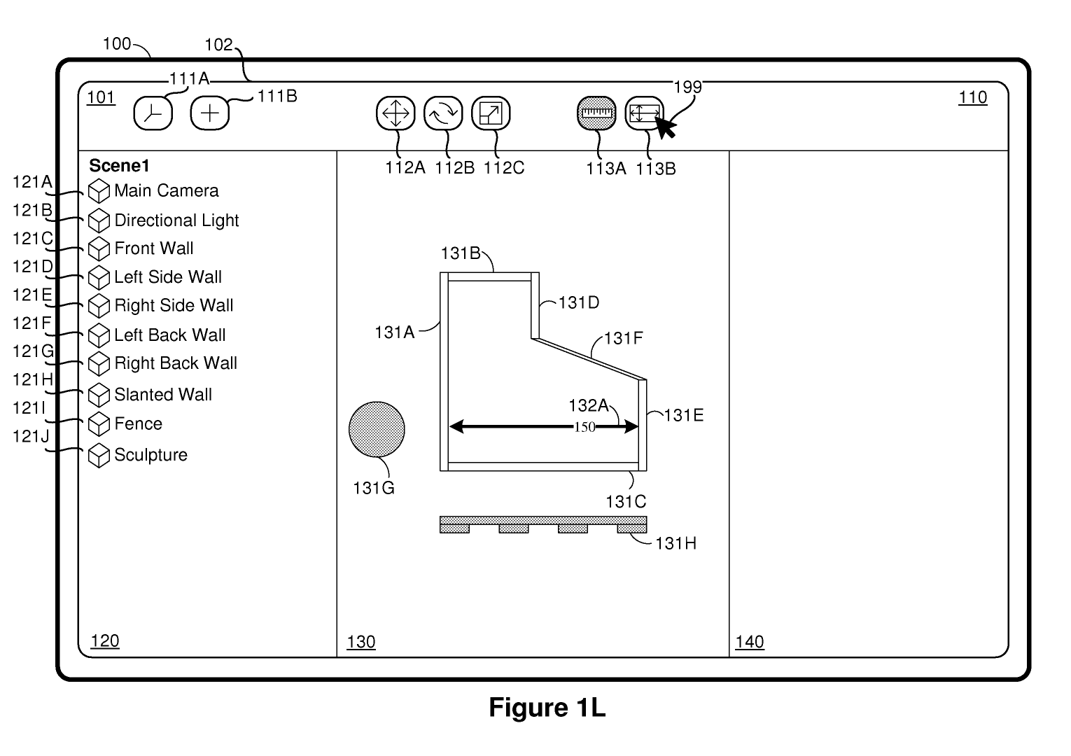

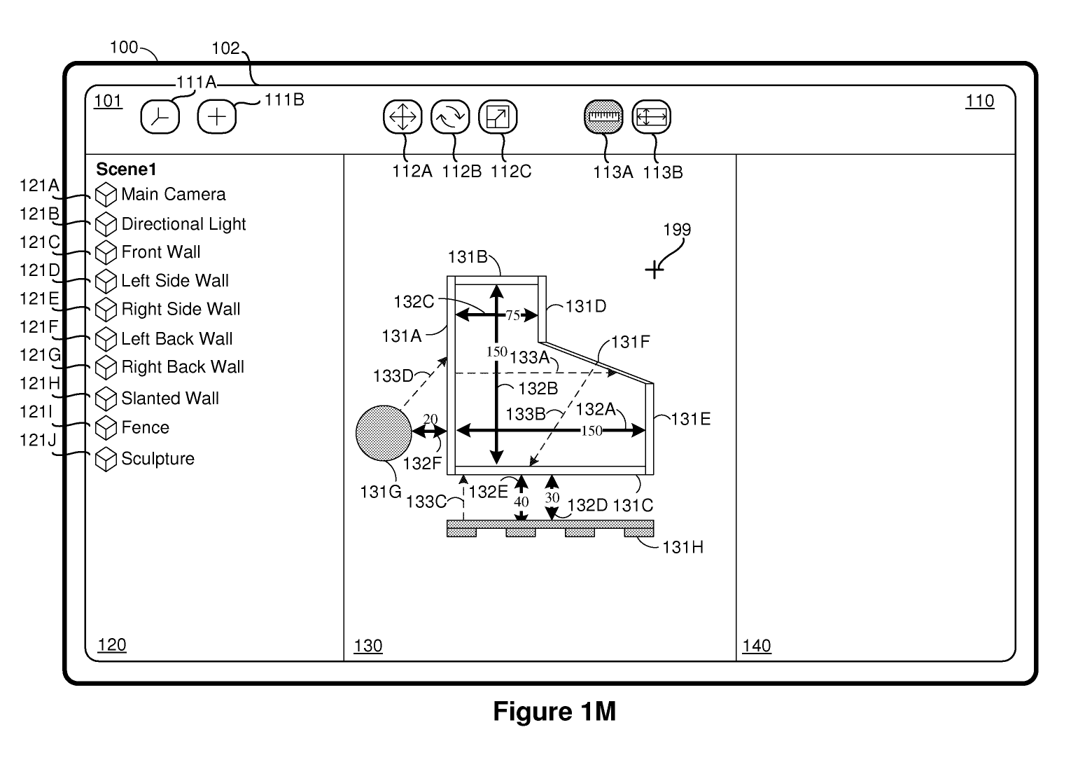

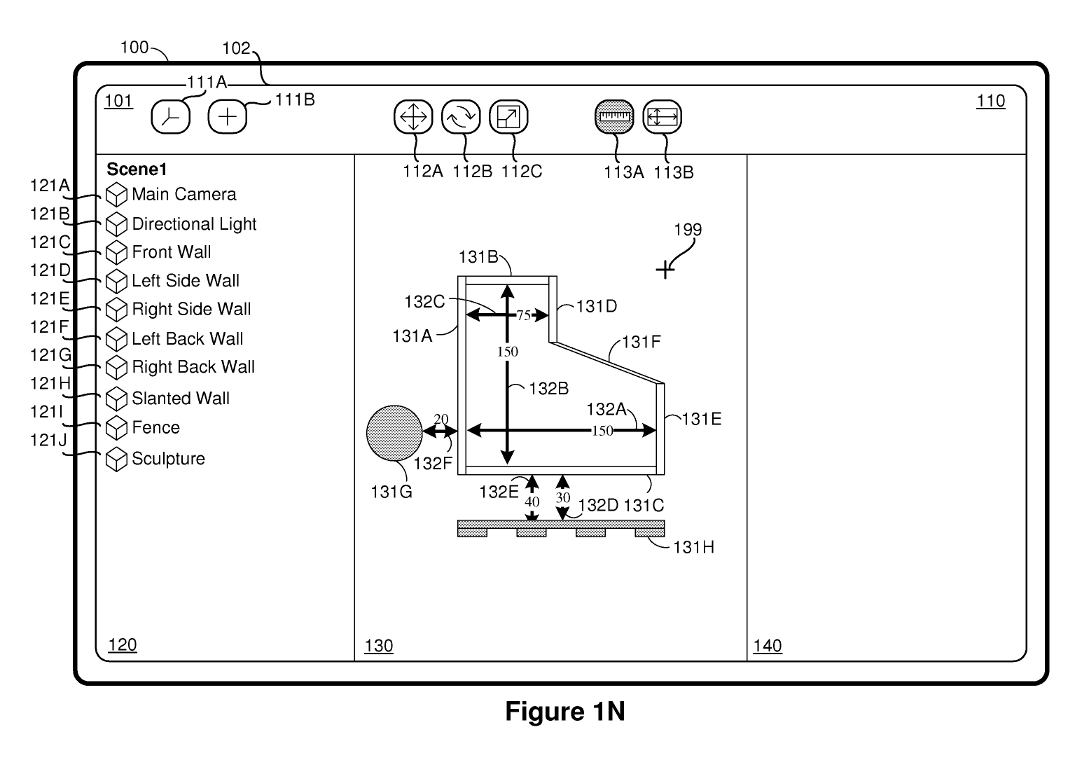

FIGS. 1A–1N illustrate an electronic device 100 including a display 102. Rendered on the display 102 is a scene composing user interface 101 that facilitates the composition of a scene including one or more objects. The scene composing user interface 101 includes a toolbar region 110, a hierarchy region 120, a preview region 130, and an inspector region 140. The scene composing user interface 101 further includes a cursor 199 for selecting various user interface elements of the scene composing user interface 101.

The toolbar region 110 includes a new scene affordance 111A which, when selected, opens a new scene. In various implementations, upon selection of the new scene affordance 111A, a window is displayed allowing a user to select various options for the new scene. The toolbar region 110 includes an add object affordance 111B which, when selected, adds an object to the currently opened scene. In various implementations, upon selection of the add object affordance 111B, a window is displayed allowing a user to select the object to be added to the currently opened scene.

The toolbar region 110 includes a position manipulation affordance 112A which, when selected, sets a manipulation mode of the scene composing user interface 101 to a position manipulation mode. While in the position manipulation mode, interactions with a representation of an object in the preview region 130 change a position of the object. The toolbar region 110 includes a rotation manipulation affordance 112B which, when selected, sets the manipulation mode of the scene composing user interface 101 to a rotation manipulation mode. While in the rotation manipulation mode, interactions with a representation of an object in the preview region 130 change a rotation of the object. The toolbar region 110 includes a size manipulation affordance 112C which, when selected, sets the manipulation mode of the scene composing user interface 101 to a size manipulation mode. While in the size manipulation mode, interactions with a representation of an object in the preview region 130 change a size of the object.

The toolbar region 110 includes a measurement affordance 113A which, when selected, sets a measurement mode of the scene composing user interface 101. While in the measurement mode, interactions with a representations of objects in the preview region 130 causes display of an indication of a distance between the objects. The toolbar region 110 includes a blueprint affordance 113B which, when selected, causes display of multiple indications of distance between different pairs of objects.

Additional functionality of the affordances of the toolbar region 110 are described further below. Further, although certain affordances of the toolbar region 110 are illustrated in FIGS. 1A–1N, it is to be appreciated that the toolbar region 110 can include other affordances with other functions.

The hierarchy region 120 includes textual representations of the objects of the currently opened scene arranged in a hierarchy, in which child objects of parent objects are displayed in association with their respective parent object and with an indication that a respective child object is a child object of the respective parent object. In FIGS. 1A–1N, a first scene is opened in the scene composing user interface 101. In FIG. 1A, the hierarchy region 120 includes a textual representation of a main camera object of the first scene 121A and a textual representation of a directional light object of the first scene 121B.

The preview region 130 includes graphical representations of the objects of the currently opened scene. In FIG. 1A, the preview region 130 is blank as there are no visible objects of the first scene.

The inspector region 140 includes indications of properties of a selected object and indications of the values of those properties. In FIG. 1A, the inspector region 140 is blank as there is no object selected.

FIGS. 1A–1N illustrate the electronic device 100 (and the displayed scene composing user interface 101) during a series of time periods. In various implementations, each time period is an instant, a fraction of a second, a few seconds, a few hours, a few days, or any length of time.

FIG. 1A illustrates the electronic device 100 during a first time period. During the first time period, the cursor 199 is displayed over the add object affordance 111B within the toolbar region 110.

FIG. 1B illustrates the electronic device 100 during a second time period subsequent to the first time period. Between the first time period and the second time period, the add object affordance 111B has been selected to add a cube object to the scene. Thus, during the second time period, the hierarchy region 120 includes a textual representation of the cube object 121C. Further, during the second time period, the preview region 130 includes a graphical representation of the cube object 131A. The textual representation of the cube object 121C is displayed in a different manner than the textual representations of the other object to indicate that the cube object is selected. For example, in FIG. 1B, the graphical representation of the cube object 121C is displayed with a gray background rather than a white background. Further, the graphical representation of the cube object 131A is displayed with a manipulator to indicate that the cube object is selected. In particular, because the manipulation mode of the scene composing user interface 101 is set to a position manipulation mode, the graphical representation of the cube object 131A is displayed with a position manipulator 132 to indicate that the cube object is selected. The position manipulation affordance 112A is displayed in a different manner than the other manipulation affordances to indicate that the scene composing user interface 101 is set to the position manipulation mode. In particular, in FIG. 1B, the position manipulation affordance 112A is displayed with a gray background rather than a white background.

Because the cube object is selected, the inspector region 140 includes indications of properties of the cube object and indications of values of those properties. For example, in FIG. 1B, the inspector region 140 includes an indication of a position property of the cube object 141A, an indication of a size property of the cube object 141B, and an indication of a rotation property of the cube object 141C. In respective association, the inspector region includes an indication of the value of the position property of the cube object 142A, an indication of the value of the size property of the cube object 142B, and an indication of the value of the rotation property of the cube object 142C.

Although only a few properties of the cube object are illustrated in FIG. 1B, it is to be appreciated that the inspector region 140 can includes indications of other properties and indications of their values. For example, in various implementations, the inspector region 140 can include indications of a color or opacity of the cube object.

During the second time period, the value of the position property of the cube object (as indicated by the indication of the value of the position property of the cube object 142A) is “x:0 y:0 z:0” indicating that the cube object is centered at the origin of a three-dimensional coordinate system of the first scene. During the second time period, the value of the size property of the cube object (as indicated by the indication of the value of the size property of the cube object 142B) is “w:100 h:100 d:100” indicating that the cube object has a width, height, and depth of 100 units. During the second time period, the value of the rotation property of the cube object (as indicated by the indication of the value of the rotation property of the cube object 142C) is “x:0 y:0 z:0” indicating that the cube object is not rotated with respect to any of the axes of the three-dimensional coordinate system of the first scene.

The cube object has a three-dimensional coordinate system that is related to the three-dimensional coordinate system of the first scene via a transform. The position manipulator 132 includes three arrows pointing in the directions of the three axes of the three-dimensional coordinate system of the cube object. By interacting with the position manipulator 132 (e.g., using the cursor 199), the position of the cube object in the three-dimensional coordinate system of the first scene can be changed. In particular, by interacting with a particular arrow of the position manipulator 132, the position of the cube object in the direction of the particular arrow can be changed. During the second time period, the cursor 199 is displayed over a particular arrow of the position manipulator 132.

FIG. 1C illustrates the electronic device 100 during a third time period subsequent to the second time period. Between the second time period and the third time period, the cursor 199 has interacted with the position manipulator 132 to change the position of the cube object. Thus, during the third time period as compared to the second time period, the graphical representation of the cube object 131A is moved. Further, during the third time period, the value of the position property of the cube object (as indicated by the indication of the value of the position property of the cube object 142A) is changed to “x:50 y:0 z:0” indicating that that the cube object has moved 50 units along the x-axis of the three-dimensional coordinate system of the first scene. Because the graphical representation of the cube object 131A has moved, the position manipulator 132 has correspondingly moved to be centered in the three-dimensional coordinate system of the cube object. During the third time period, the cursor 199 is displayed over the rotation manipulation affordance 112B.

FIG. 1D illustrates the electronic device 100 during a fourth time period subsequent to the third time period. Between the third time period and the fourth time period, the rotation manipulation affordance 112B has been selected to set the manipulation mode of the scene composing user interface 101 to a rotation manipulation mode. Thus, in FIG. 1D, the rotation manipulation affordance 112B is displayed with a gray background (and the position manipulation affordance 112A has reverted to a white background). Further, the position manipulator 132 is replaced with a rotation manipulator 133.

The rotation manipulator 133 includes three circles within planes perpendicular to the three axes of the three-dimensional coordinate system of the cube object. By interacting with the rotation manipulator 133 (e.g., using the cursor 199), the rotation of the cube object in the three-dimensional coordinate system of the first scene can be changed. In particular, by interacting with a particular circle of the rotation manipulator 133, the rotation of the cube object around the corresponding axes can be changed. During the fourth time period, the cursor 199 is displayed over a particular circle of the rotation manipulator 133.

FIG. 1E illustrates the electronic device 100 during a fifth time period subsequent to the fourth time period. Between the fourth time period and the fifth time period, the cursor 199 has interacted with the rotation manipulator 133 to change the rotation of the cube object. Thus, during the fifth time period as compared to the fourth time period, the graphical representation of the cube object 131A is rotated. Further, during the fifth time period, the value of the rotation property of the cube object (as indicated by the indication of the value of the rotation property of the cube object 142C) is changed to “x:0 y:0 z:45” indicating that that the cube object has rotated 45 units around the z-axis of the three-dimensional coordinate system of the first scene. During the fifth time period, the cursor 199 is displayed over the size manipulation affordance 112C.

FIG. 1F illustrates the electronic device 100 during a sixth time period subsequent to the fifth time period. Between the fifth time period and the sixth time period, the size manipulation affordance 112C has been selected to set the manipulation mode of the scene composing user interface 101 to a size manipulation mode. Thus, in FIG. 1F, the size manipulation affordance 112C is displayed with a gray background (and the rotation manipulation affordance 112B has reverted to a white background). Further, the rotation manipulator 133 is replaced with a size manipulator 134.

The size manipulator 134 includes three circle-terminated lines pointing in the direction of the three axes of the three-dimensional coordinate system of the cube object. By interacting with the size manipulator 134 (e.g., using the cursor 199), the size of the cube object in the three-dimensional coordinate system of the first scene can be changed. In particular, by interacting with a particular line of the size manipulator 134, the size of the cube object in the direction of the line can be changed. Thus, by interacting with a width line of the size manipulator 134, the width of the cube object can be changed. Similarly, by interacting with a height line of the size manipulator 134, the height of the cube object can be changed and by interacting with a depth line of the size manipulator 134, the depth of the cube object can be changed. During the sixth time period, the cursor 199 is displayed over the width line of the size manipulator 134.

FIG. 1G illustrates the electronic device 100 during a seventh time period subsequent to the sixth time period. Between the sixth time period and the seventh time period, the cursor 199 has interacted with the width line of the size manipulator 134 to change the width of the cube object. Thus, during the seventh time period as compared to the sixth time period, the graphical representation of the cube object 131A is narrower. Further, during the seventh time period, the value of the size property of the cube object (as indicated by the indication of the value of the size property of the cube object 142B) is changed to “w:20 h:100 d:100” indicating that that the cube object is one-fifth as wide in the three-dimensional coordinate system of the cube object. In various implementations, when the size of an object is changed, both sides of the object change position and the center remains stationary. In various implementations, when the size of an object is changed, one side of the object changes position and the center moves in the direction of the size increase or decrease. Thus, during the seventh time period, the value of the position property of the cube object (as indicated by the indication of the value of the position property of the cube object 142A) is changed to “x:10 y:0 z:0” indicating that the center of the cube object has moved to the left 40 units (half of the change in width). During the seventh time period, the cursor 199 is displayed over the add object affordance 111B.

FIG. 1H illustrates the electronic device 100 during an eighth time period subsequent to the seventh time period. Between the seventh time period and the eighth time period, a user has interacted with the scene composing user interface 101 to add a number of cube objects; change the size, position, and rotation of those objects (and the initial cube object); and rename the objects.

Thus, the textual representation of the cube object 121C has been changed to read “Front Wall” in the hierarchy region 120 and the graphical representation of the cube object 131A changed size, position, and rotation within the preview region 130. For consistency, the cube object will henceforth be referred to as the front wall object. The front wall object is represented by the textual representation of the front wall object 121C and the graphical representation of the front wall object 131A.

During the eighth time period, the first scene includes a front wall object, a left side wall object, a right side wall object, a left back wall object, a right back wall object, and a slanted wall object to form the outline of a building. Accordingly, the hierarchy region 120 includes a textual representation of the front wall object 121C, a textual representation of the left side wall object 121D, a textual representation of the right side wall object 121E, a textual representation of the left back wall object 121F, a textual representation of the right back wall object 121G, and a textual representation of the slanted wall object 121H. Similarly, the preview region includes a graphical representation of the front wall object 131A, a graphical representation of the left side wall object 131B, a graphical representation of the right side wall object 131C, a graphical representation of the left back wall object 131D, a graphical representation of the right back wall object 131E, and a graphical representation of the slanted wall object 131F.

Because the slanted wall object is selected, the size manipulator 134 is displayed in association with the graphical representation of the slanted wall object 131F and the inspector region 140 includes indications of properties of the slanted wall object and indications of values of those properties. For example, in FIG. 1H, the inspector region 140 includes an indication of a position property of the slanted wall object 143A, an indication of a size property of the slanted wall object 143B, and an indication of a rotation property of the slanted wall object 143C. In respective association, the inspector region includes an indication of the value of the position property of the slanted wall object 144A, an indication of the value of the size property of the slanted wall object 144B, and an indication of the value of the rotation property of the slanted wall object 144C. During the eighth time period, the cursor 199 is displayed over the add object affordance 111B.

FIG. 1I illustrates the electronic device 100 during a ninth time period subsequent to the eighth time period. Between the eighth time period and the ninth time period, a user has interacted with the scene composing user interface 101 to add a fence object and a sculpture object and change the size, position, and rotation of those objects.

During the ninth time period, the first scene includes a fence object and a sphere object. Accordingly, the hierarchy region 120 includes a textual representation of the fence object 121I and a textual representation of the sculpture object 121J and the preview region 130 includes a graphical representation of the fence object 131H and a graphical representation of the sculpture object 131G.

Because the sculpture object is selected, the size manipulator 134 is displayed in association with the graphical representation of the sculpture object 131G and the inspector region 140 includes indications of properties of the sculpture object and indications of values of those properties. For example, in FIG. 1I, the inspector region 140 includes an indication of a position property of the sculpture object 145A, an indication of a size property of the sculpture object 145B, and an indication of a rotation property of the sculpture object 145C. In respective association, the inspector region includes an indication of the value of the position property of the sculpture object 146A, an indication of the value of the size property of the sculpture object 146B, and an indication of the value of the rotation property of the sculpture object 146C. During the ninth time period, the cursor 199 is displayed over the measurement affordance 113A.

FIG. 1J illustrates the electronic device 100 during a tenth time period subsequent to the ninth time period. Between the ninth time period and the tenth time period, a user has selected the measurement affordance 113A. In response to detecting selection of the measurement affordance 113A, the scene composing user interface 101 is set to a measurement mode rather than a manipulation mode. Thus, the measurement affordance 113A is displayed in a different manner than the manipulation affordances 112A–112C.

In the measurement mode, no manipulator is displayed and the cursor 199 changes from a selecting icon (e.g., an arrow) to a targeting icon (e.g., a cross) when in the preview region 130. In FIG. 1J, the cursor 199 is displayed on the interior surface of the graphical representation of the right back wall object 131E.

FIG. 1K illustrates the electronic device 100 during an eleventh period subsequent to the tenth time period. Between the tenth time period and the eleventh time period, a user has, while pressing down an input button, moved the cursor 199 from the interior surface of the graphical representation of the right back wall object 131E to the interior surface of the graphical representation of the front wall object 131A, then released the input button. In response to this input, the preview region 130 includes a first distance indicator 132A spanning between the start point and the end point of the input. The first distance indicator 132A indicates the distance between the right back wall and the front wall, e.g., 150 units.

FIG. 1L illustrates the electronic device 100 during a twelfth time period subsequent to the eleventh time period. Between the eleventh time period and the twelfth time period a user has changed the perspective of preview region 130 from a first location to a second location providing a top-down view of the first scene. In FIG. 1L, the cursor 199 is displayed over the blueprint affordance 113B.

FIG. 1M illustrates the electronic device 100 during a thirteenth time period subsequent to the twelfth time period. Between the twelfth time period and the thirteenth time period, the electronic device 100 detects selection of the blueprint affordance 113B.

In response to detecting selection of the blueprint affordance 113B, the preview region 130 includes a plurality of distance indicators 132B–132F. The preview region 130 includes a second distance indicator 132B indicating a distance between the left side wall object and the right side wall object spanning between the graphical representation of the left side wall object 131B and the graphical representation of the right side wall object 131C. The preview region 130 includes a third distance indicator 132C indicating a distance between the left back wall object and the front wall object spanning between the graphical representation of the left back wall object 131D and the graphical representation of the front wall object 131A. The preview region 130 includes a fourth distance indicator 132D indicating the distance between the right side wall object and the upper crossbar of the fence object spanning between the graphical representation of the right side wall object 131C and the upper crossbar of the graphical representation of the fence object 131H. The preview region 130 includes a fifth distance indicator 132E indicating the distance between the right side wall object and a post of the fence object spanning between the graphical representation of the right side wall object 131C and the post of the graphical representation of the fence object 131H. The preview region 130 includes a sixth distance indicator 132F indicating the distance between the sculpture object and the front wall object spanning between the graphical representation of the sculpture object 131G and the graphical representation of the front wall object 131A.

In various implementations, the electronic device 100 determines the distances using ray tracing. For each surface of each object, a ray is projected from the center of the surface perpendicular to the surface until it intersects with another object. The length of the ray is a distance between the two objects. If a display criterion is satisfied, a distance indicator indicating the distance is displayed at the location of the ray.

In various implementations, the display criterion is satisfied for a distance when the ray intersects the other object at an angle satisfying an intersection criterion. In various implementations, the intersection criterion is satisfied when the angle is a right angle. For example, the ray projected from the center of and perpendicular to the interior surface of the left side wall object intersects the interior surface of the right side wall object at a right angle. Thus, the second distance indicator 132B is displayed indicating the length of the ray. However, the ray projected from the center of and perpendicular to the interior surface of the front wall object intersects the slanted wall object at an approximately 30 degree angle. Thus, no distance indicator is displayed at the location of the first arrow 133A. Similarly, the ray projected from the center of and perpendicular to the interior surface of the slanted wall object intersects the right side wall object at an approximately 60 degree angle. Thus, no distance indicator is displayed at the location of the second arrow 133B. In various implementations, the intersection criterion is satisfied when the angle is within a range of angle values, such as between 85 and 95 degrees.

In various implementations, the display criterion is satisfied when the distance is sufficiently different than other nearby distances. For example, the ray projected from the center of and perpendicular to the wall-facing surface of the upper crossbar of the fence object intersects the right side wall object with a length of 30 units, which is sufficiently different than the length of the ray projected from the center of and perpendicular to the wall-facing surface of the post of the fence object that intersects the right side wall object (which is 40 units). Accordingly, the fourth distance indicator 132D is displayed. However, the ray projected from the center of an perpendicular to the wall-facing surface of another post of the fence object intersects the right side wall object with a length of 40 units, which is not sufficiently different than the length of the ray projected from the center of and perpendicular to the wall-facing surface of the post of the fence object that intersects the right side wall object (which is also 40 units). Thus, no distance indicator is displayed at the location of the third arrow 133C.

In various implementations, the display criterion is satisfied when the distance is the smallest distance between the two objects. For example, a first ray projected from the center of and perpendicular to the surface of the sculpture object closest to the front wall object intersects the front wall object and has a length of 20 units. A second ray projected from the center of and perpendicular to a different surface of the sculpture object also intersects the front wall object and has a length of 40 units. Accordingly, the sixth distance indicator 132F is displayed, but no distance indicator is displayed at the location of the fourth arrow 133D.

In various implementations, the display criterion is satisfied when a display score for the distance satisfied a value criterion. For example, when the display score is greater than a threshold. In various implementations, the display score is determined based on one or more of the factors described above, e.g., the angle of intersection, the uniqueness of the distance compared to other nearby distances, and being the only distance between the two objects.

It is to be appreciated that the scene composing user interface 101 does not display the arrows 133A–133D, but they are included in FIG. 1M for illustrative purposes only. For clarity, FIG. 1N illustrates the electronic device 100 during a thirteenth time period without the arrows 133A–133D.

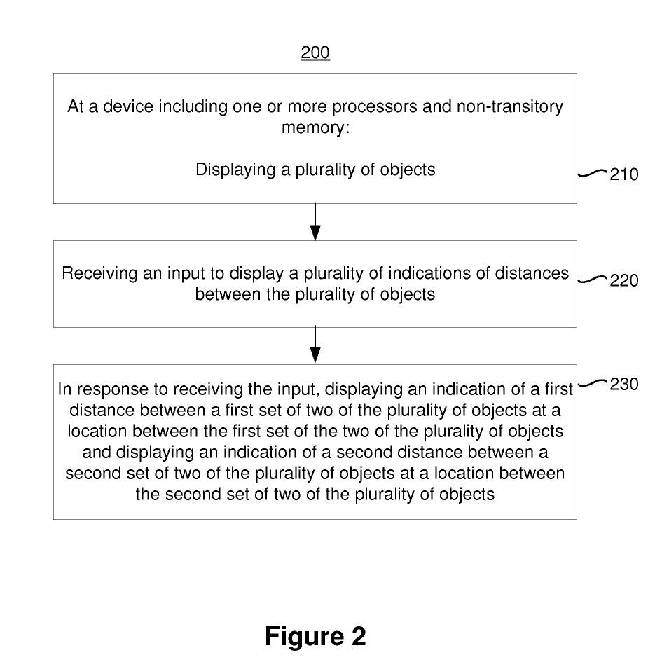

FIG. 2 is a flowchart representation of a method 200 of displaying distances between objects in accordance with some implementations. In various implementations, the method 200 is performed by an electronic device. In various implementations, the method 200 is performed by a device one or more processors and non-transitory memory. In some implementations, the method 200 is performed by processing logic, including hardware, firmware, software, or a combination thereof. In some implementations, the method 200 is performed by a processor executing instructions (e.g., code) stored in a non-transitory computer-readable medium (e.g., a memory).

The method 200 begins, in block 210, with the device displaying a plurality of objects. In various implementations, displaying an object includes displaying a graphical representation of the object. For example, in FIG. 1L, the electronic device 100 displays, among other objects, the graphical representation of the front wall object 131A, the graphical representation of the left side wall object 131B, the graphical representation of the right back wall object 131E, the graphical representation of the fence object 131H, and the graphical representation of the sculpture object 131G.

The method 200 continues, in block 220, with the device receiving an input to display a plurality of indications of distances between the plurality of objects. In various implementations, receiving the input includes detecting selection of an affordance. For example, in FIG. 1L, the electronic device 100 displays the blueprint affordance 113B which, when selected, causes display of a plurality of indications of distances between objects. In various implementations, receiving the input includes detecting a keyboard shortcut. In various implementations, receiving the input includes detecting a vocal command.

The method 200 continues, in block 230, with the device, in response to receiving the input, displaying an indication of a first distance between a first set of two of the plurality of objects at a location between the first set of the two of the plurality of objects and displaying an indication of a second distance between a second set of two of the plurality of objects at a location between the second set of the two of the plurality of objects. For example, in FIG. 1N, in response to detecting selection of the blueprint affordance 113B, the preview region includes the second distance indicator 132B indicating the distance between the left side wall object and the right side wall object and the third distance indicator 132C indicating the distance between the front wall object and the left back wall object.

In various implementations, the method 200 further includes, in response to receiving the input, determining the first distance and determining the second distance. In various implementations, determining a distance includes ray tracing. For example, in various implementations, determining a distance includes determining the length of a ray (or line segment) from the center of and perpendicular to a surface of a first object to a second object. Thus, in various implementations, determining the first distance includes determining a length of a ray from a center of and perpendicular to a surface of a first object of the first set to a second object of the first set.

In various implementations, the method 200 includes determining a respective distance based on a ray cast from each surface to the closest intersecting object (or determining that the ray does not intersect any object). However, in various implementations, not all such determined distances are displayed with an indication of the distance (or distance indicator). Thus, in various implementations, the method 200 includes, in response to receiving the input, determining that the first distance and the second distance each satisfy a display criterion. Thus, displaying the indication of the first distance and displaying the indication of the second distance (in block 230) is performed in response to determining that the first distance and the second distance each satisfy the display criterion.

In various implementations, the method 200 includes in response to receiving the input, determining a third distance between a third set of two of the plurality of object, determining that the third distance fails to satisfy the display criterion, and forgoing display of an indication of the third distance.

In various implementations, the display criterion is satisfied when a ray from the center of and perpendicular to a surface of a first object intersects a second object at an angle satisfying an intersection criterion. In particular, the display criterion is satisfied for the first distance when a ray from a center of and perpendicular to a surface of a first object of the first set intersects with the second object of the first set at an angle satisfying an intersection criterion. In various implementations, the intersection criterion is satisfied when the angle is a right angle. In various implementations, the intersection criterion is satisfied when the angle has a value that is within a range of angle values, e.g., 85–95 degrees.

For example, in FIG. 1M, the electronic device 100 displays the second distance indicator 132B because the ray from the center of and perpendicular to the interior surface of the left side wall object intersects the right side wall object at a right angle. In contrast, the electronic device 100 does not display a distance indicator at the location of the first arrow 133A because the ray from the center of and perpendicular to the interior surface of the front side wall object intersects the slanted wall object at an approximately 30 degree angle.

In various implementations, the display criterion is satisfied when the distance is sufficiently different than other nearby distances. In particular, the display criterion is satisfied for the first distance when, for each distance having an indication displayed within a neighborhood of the first distance, a difference between the distance and the first distance satisfies a difference criterion. In various implementations, the difference criterion is satisfied when the difference between the distance and the first distance is greater than a difference threshold. In various implementations, the difference threshold is a fixed number. In various implementations, the difference threshold is a percentage of the first distance. In various implementations, the difference threshold is based on a relative distance between the distance and the first distance (e.g., the size of the neighborhood).

For example, in FIG. 1M, the electronic device 100 displays the fourth distance indicator 132D because the ray from the center of and perpendicular to the wall-facing surface of the upper crossbar of the fence object to the right side wall object has a length that is sufficiently different from the length of the ray from the center of and perpendicular to the wall-facing surface of the post of the fence object displayed by the fifth distance indicator 132E. In contrast, the electronic device 100 does not display a distance indicator at the location of the third arrow 133C because the ray from the center of and perpendicular to the wall-facing surface of the other post to the right side wall object has a length that is too similar (in fact, identical) to the length of the ray from the center of an perpendicular to the wall-facing surface of the post of the fence object displayed by the fifth distance indicator 132E.

In various implementations, the display criterion is satisfied when the distance is the only distance having an indication displayed between the two objects. In particular, the display criterion is satisfied when each other distance having an indication displayed is not a distance between the first set of the two of the plurality of objects. For example, in FIG. 1M, the electronic device 100 displays the sixth distance indicator 132F between the sculpture object and the front wall object, but not at the location of the fourth arrow 133D because the sixth distance indicator 132F is displayed.

In various implementations, when only one indication of distance is displayed for a set of objects, the indication of distance indicates the minimum distance between the objects. In various implementations, the indication of distance indicates the distance of a ray that intersects both objects at 90 degrees. In various implementations, multiple indications of distance are displayed for a set of objects. For example, in FIG. 1M, the electronic device 100 displays the fourth distance indicator 132D between the fence object and the right side wall object and the fifth distance indicator 132E between the fence object and the right side wall object.

In various implementations, the method 200 includes determining a display score for each surface of each object and displaying indications for distances having a display score above a threshold (or otherwise satisfying a value criterion). In particular, the method 200 includes, determining a display score for the first distance, wherein the display criterion is satisfied for the first distance when the display score satisfies a value criterion.

In various implementations, the display score is determined based on one or more of the factors described above, e.g., the angle of intersection, the uniqueness of the distance compared to other nearby distances, and the uniqueness of the distance between the two objects. For example, in FIG. 1M, the electronic device 100 determines a display score that does not breach the threshold for the distance represented by the fourth arrow 133D that is diminished by the display of the sixth distance indicator 132F between the same two objects and further diminished by the angle of intersection being 45 degrees. However, the electronic device 100 determines a display score that does breach the threshold for the distance represented by the fourth distance indicator 132D that is diminished by the display of the fifth distance indicator 132E between the same two objects, but increased because the angle of intersection is 90 degrees. In contract, the electronic device 100 determines a display score that does not breach the threshold for the distance represented by the third arrow 133C that is diminished by the display of the fourth distance indicator 132D and fifth distance indicator 132E between the same two objects, increased because the angle of intersection is 90 degrees, but further diminished by its similarity to the fifth distance indicator 132E.

In various implementations, the first set and the second set contain no common objects. For example, in FIG. 1M, the second distance indicator 132B indicates a distance between the left side wall object and the right side wall object and the third distance indicator 132C indicates a distance between the front wall object and the left back wall object. In various implementations, the first set and the second set each contain a common object. For example, the second distance indicator 132B indicates a distance between the left side wall object and the right side wall object and the fourth distance indicator 132D indicates a distance between the right side wall object and the fence object. In various implementations, the first set and the second set each contain two common objects. For example, both the fourth distance indicator 132D and the fifth distance indicator 132E indicate a distance between the right side wall object and the fence object.

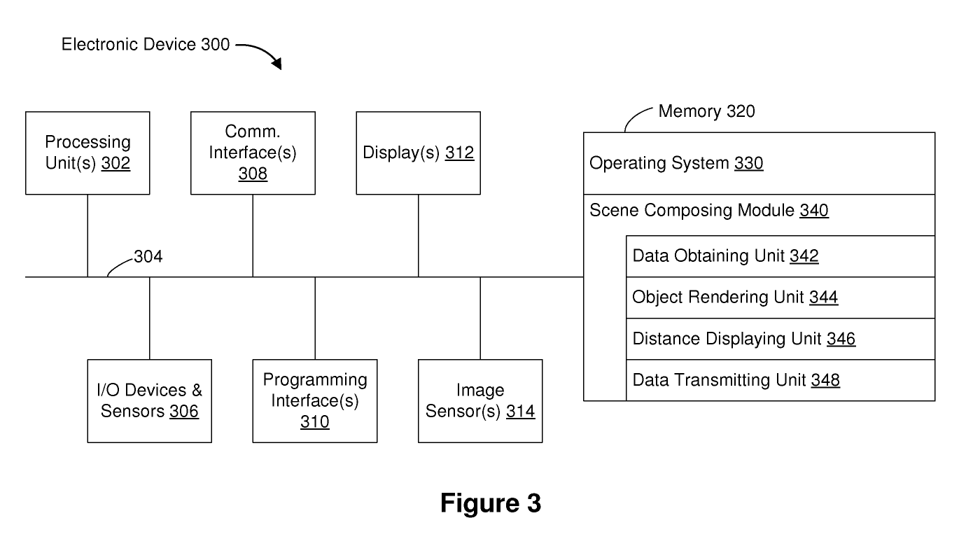

FIG. 3 is a block diagram of an example of an electronic device 300 in accordance with some implementations. While certain specific features are illustrated, those skilled in the art will appreciate from the present disclosure that various other features have not been illustrated for the sake of brevity, and so as not to obscure more pertinent aspects of the implementations disclosed herein. To that end, as a non-limiting example, in some implementations the electronic device 300 includes one or more processing units 302 (e.g., microprocessors, ASICs, FPGAs, GPUs, CPUs, processing cores, and/or the like), one or more input/output (I/O) devices and sensors 306, one or more communication interfaces 308 (e.g., USB, FIREWIRE, THUNDERBOLT, IEEE 802.3x, IEEE 802.11x, IEEE 802.16x, GSM, CDMA, TDMA, GPS, IR, BLUETOOTH, ZIGBEE, and/or the like type interface), one or more programming (e.g., I/O) interfaces 310, one or more displays 312, one or more optional interior- and/or exterior-facing image sensors 314, a memory 320, and one or more communication buses 304 for interconnecting these and various other components.

In some implementations, the one or more communication buses 304 include circuitry that interconnects and controls communications between system components. In some implementations, the one or more I/O devices and sensors 306 include at least one of an inertial measurement unit (IMU), an accelerometer, a gyroscope, a thermometer, one or more physiological sensors (e.g., blood pressure monitor, heart rate monitor, blood oxygen sensor, blood glucose sensor, etc.), one or more microphones, one or more speakers, a haptics engine, one or more depth sensors (e.g., a structured light, a time-of-flight, or the like), and/or the like.

In some implementations, the one or more displays 312 are configured to display a virtual environment. In some implementations, the one or more displays 312 correspond to holographic, digital light processing (DLP), liquid-crystal display (LCD), liquid-crystal on silicon (LCoS), organic light-emitting field-effect transitory (OLET), organic light-emitting diode (OLED), surface-conduction electron-emitter display (SED), field-emission display (FED), quantum-dot light-emitting diode (QD-LED), micro-electro-mechanical system (MEMS), and/or the like display types. In some implementations, the one or more displays 312 correspond to diffractive, reflective, polarized, holographic, etc. waveguide displays. In one example, the electronic device 300 includes a single display. In another example, the electronic device includes a display for each eye of the user. In some implementations, the one or more displays 312 are capable of presenting XR (extended reality) and VR (virtual reality) content.

In some implementations, the one or more image sensors 314 are configured to obtain image data that corresponds to at least a portion of the face of the user that includes the eyes of the user (any may be referred to as an eye-tracking camera). In some implementations, the one or more image sensors 314 are configured to be forward-facing so as to obtain image data that corresponds to the physical environment as would be viewed by the user if the electronic device 300 was not present (and may be referred to as a scene camera). The one or more optional image sensors 314 can include one or more RGB cameras (e.g., with a complimentary metal-oxide-semiconductor (CMOS) image sensor or a charge-coupled device (CCD) image sensor), one or more infrared (IR) cameras, one or more event-based cameras, and/or the like.

The memory 320 includes high-speed random-access memory, such as DRAM, SRAM, DDR RAM, or other random-access solid-state memory devices. In some implementations, the memory 320 includes non-volatile memory, such as one or more magnetic disk storage devices, optical disk storage devices, flash memory devices, or other non-volatile solid-state storage devices. The memory 320 optionally includes one or more storage devices remotely located from the one or more processing units 302. The memory 320 comprises a non-transitory computer readable storage medium. In some implementations, the memory 320 or the non-transitory computer readable storage medium of the memory 320 stores the following programs, modules and data structures, or a subset thereof including an optional operating system 330 and an environment presentation module 340.

The operating system 330 includes procedures for handling various basic system services and for performing hardware dependent tasks. In some implementations, the scene composing module 340 is configured to present a scene composing user interface to the user via the one or more displays 312. To that end, in various implementations, the scene composing module 340 includes a data obtaining unit 342, an object rendering unit 344, an distance displaying unit 346, and a data transmitting unit 348.

In some implementations, the data obtaining unit 342 is configured to obtain data (e.g., presentation data, interaction data, sensor data, location data, etc.) from the other components of the electronic device 300 and/or a different electronic device. To that end, in various implementations, the data obtaining unit 342 includes instructions and/or logic therefor, and heuristics and metadata therefor.

In some implementations, the object rendering unit 344 is configured to display graphical representations of objects in the scene composing user interface. To that end, in various implementations, the object rendering unit 344 includes instructions and/or logic therefor, and heuristics and metadata therefor.

In some implementations, the distance displaying unit 346 is configured to, in response to user input, display a plurality of indications of distances between the objects. To that end, in various implementations, the distance displaying unit 346 includes instructions and/or logic therefor, and heuristics and metadata therefor.

In some implementations, the data transmitting unit 348 is configured to transmit data (e.g., presentation data, location data, etc.) to other components of the electronic device 300 and/or a different electronic device. To that end, in various implementations, the data transmitting unit 348 includes instructions and/or logic therefor, and heuristics and metadata therefor.

Although the data obtaining unit 342, the object rendering unit 344, the distance displaying unit 346, and the data transmitting unit 348 are shown as residing on a single device (e.g., the electronic device 300), it should be understood that in other implementations, any combination of the data obtaining unit 342, the object rendering unit 344, the distance displaying unit 346, and the data transmitting unit 348 may be located in separate computing devices.

Moreover, FIG. 3 is intended more as a functional description of the various features that could be present in a particular implementation as opposed to a structural schematic of the implementations described herein. As recognized by those of ordinary skill in the art, items shown separately could be combined and some items could be separated. For example, some functional modules shown separately in FIG. 3 could be implemented in a single module and the various functions of single functional blocks could be implemented by one or more functional blocks in various implementations. The actual number of modules and the division of particular functions and how features are allocated among them will vary from one implementation to another and, in some implementations, depends in part on the particular combination of hardware, software, and/or firmware chosen for a particular implementation.

While various aspects of implementations within the scope of the appended claims are described above, it should be apparent that the various features of implementations described above may be embodied in a wide variety of forms and that any specific structure and/or function described above is merely illustrative. Based on the present disclosure one skilled in the art should appreciate that an aspect described herein may be implemented independently of any other aspects and that two or more of these aspects may be combined in various ways. For example, an apparatus may be implemented and/or a method may be practiced using any number of the aspects set forth herein. In addition, such an apparatus may be implemented and/or such a method may be practiced using other structure and/or functionality in addition to or other than one or more of the aspects set forth herein.

It will also be understood that, although the terms “first,” “second,” etc. may be used herein to describe various elements, these elements should not be limited by these terms. These terms are only used to distinguish one element from another. For example, a first node could be termed a second node, and, similarly, a second node could be termed a first node, which changing the meaning of the description, so long as all occurrences of the “first node” are renamed consistently and all occurrences of the “second node” are renamed consistently. The first node and the second node are both nodes, but they are not the same node.

The terminology used herein is for the purpose of describing particular implementations only and is not intended to be limiting of the claims. As used in the description of the implementations and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

What is claimed is:

1. A method comprising:
at a device having one or more processors and non-transitory memory:
displaying a plurality of objects;
receiving an input to display a plurality of indications of distances between the plurality of objects; and
in response to receiving the input:
displaying an indication of a first distance between a first set of two of the plurality of objects at a location between the first set of the two of the plurality of objects; and
displaying an indication of a second distance between a second set of two of the plurality of objects at a location between the second set of the two of the plurality of objects.

2. The method of claim 1, further comprising, in response to receiving the input, determining the first distance and determining the second distance.

3. The method of claim 2, wherein determining the first distance includes determining a length of a ray from a center of and perpendicular to a surface of a first object of the first set to a second object of the first set.

4. The method of claim 1, further comprising, in response to receiving the input, determining that the first distance and the second distance each satisfy a display criterion.

5. The method of claim 4, further comprising, in response to receiving the input:
determining a third distance between a third set of two of the plurality of objects;
determining that the third distance fails to satisfy the display criterion; and
forgoing display of an indication of the third distance.

6. The method of claim 4, wherein the display criterion is satisfied for the first distance when a ray from a center of and perpendicular to a surface of a first object of the first set intersects with a second object of the first set at an angle satisfying an intersection criterion.

7. The method of claim 6, wherein the intersection criterion is satisfied when the angle is a right angle.

8. The method of claim 6, wherein the intersection criterion is satisfied when the angle has value that is within a range of angle values.

9. The method of claim 4, wherein the display criterion is satisfied for the first distance when, for each distance having an indication displayed within a neighborhood of the first distance, a difference between the distance and the first distance satisfies a difference criterion.

10. The method of claim 9, wherein the difference criterion is satisfied when the difference between the distance and the first distance is greater than a difference threshold.

11. The method of claim 4, wherein the display criterion is satisfied when each other distance having an indication displayed is not a distance between the first set of the two of the plurality of objects.

12. The method of claim 4, further comprising determining a display score for the first distance, wherein the display criterion is satisfied for the first distance when the display score satisfies a value criterion.

13. The method of claim 1, wherein the first set and the second set contain no common objects.

14. The method of claim 1, wherein the first set and the second set each contain a common object.

15. The method of claim 14, wherein the first set and the second set each contain two common objects.

16. A device comprising:
a non-transitory memory; and
one or more processors to:
display a plurality of objects;
receive an input to display a plurality of indications of distances between the plurality of objects; and
in response to receiving the input:
display an indication of a first distance between a first set of two of the plurality of objects at a location between the first set of the two of the plurality of objects; and
display an indication of a second distance between a second set of two of the plurality of objects at a location between the second set of the two of the plurality of objects.

17. The device of claim 16, wherein the one or more processors are further to, in response to receiving the input, determine that the first distance and the second distance each satisfy a display criterion.

18. The device of claim 17, wherein the display criterion is satisfied for the first distance when a ray from a center of and perpendicular to a surface of a first object of the first set intersects with a second object of the first set at an angle satisfying an intersection criterion.

19. The device of claim 17, wherein the display criterion is satisfied for the first distance when, for each distance having an indication displayed within a neighborhood of the first distance, a difference between the distance and the first distance satisfies a difference criterion.

20. A non-transitory memory storing one or more programs, which, when executed by one or more processors of a device, cause the device to:
display a plurality of objects;
receive an input to display a plurality of indications of distances between the plurality of objects; and
in response to receiving the input:
display an indication of a first distance between a first set of two of the plurality of objects at a location between the first set of the two of the plurality of objects; and
display an indication of a second distance between a second set of two of the plurality of objects at a location between the second set of the two of the plurality of objects.
